(19) United States
(12) Patent Application Publication
(10) Pub. No.: US 2022/0366848 A1
(43) Pub. Date: Nov. 17, 2022

(54) DISPLAY SUBSTRATE AND DISPLAY PANEL

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yao HUANG, Beijing (CN); Yang ZHOU, Beijing (CN)

(21) Appl. No.: 17/615,552

(22) PCT Filed: Dec. 8, 2020
(86) PCT No.: PCT/CN2020/134554

§ 371 Date: Nov. 30, 2021

(51) Int. Cl. G09G 3/3233; G09G 3/3266

(52) U.S. Cl. CPC G09G 3/3233; G09G 3/3266; G09G 2300/0819; G09G 2300/0842; G09G 2300/0861; G09G 2300/0426; G09G 2310/0286; G09G 2330/021; G09G 2310/061; G11C 19/28

(57) ABSTRACT

The present disclosure provides a display substrate and a display panel. The display substrate has a display area and a peripheral area surrounding the display area; the display area includes first and second display sub-areas; the display substrate includes a base substrate, and a driving circuit layer and multiple light-emitting devices on the base substrate; the driving circuit layer includes multiple pixel driving circuits, a gate driving circuit, and a light emission control circuit; a first electrode of each light-emitting device is electrically coupled to one pixel driving circuit; the multiple pixel driving circuits include first pixel driving circuits for providing driving signals for light-emitting devices in the first display sub-area, and second pixel driving circuits for providing driving signals for light-emitting devices in the second display sub-area; and the light emission control circuit includes first and second light emission control sub-circuits disconnected from each other.

### TECHNICAL FIELD

The present disclosure belongs to the field of display technology, and particularly relates to a display substrate and a display panel.

### BACKGROUND

With the development of technology, special-shaped screens and full screens have gradually become known to a wider public in recent years. The purpose of adopting either a special-shaped screen or a full screen is to increase the screen-to-body ratio of a display device. In order to achieve a higher screen-to-body ratio, some opening areas (e.g., openings) need to be reserved for some additional components (e.g., a camera, a sensor, etc.) in some positions of the display screen.

With the development and upgrading of display technology, organic electroluminance display (OLED for short) devices have gradually become mainstream products in the display field due to their characteristics such as self-illumination, high brightness, large contrast, low operating voltage, and applicability for flexible display.

### SUMMARY

The present disclosure aims to solve at least one of the technical problems existing in the related art, and to provide a display substrate and a display panel.

In a first aspect, embodiments of the present disclosure provide a display substrate having a display area and a peripheral area surrounding the display area; the display area includes a first display sub-area and a second display sub-area; wherein the display substrate includes a base substrate, and a driving circuit layer and a plurality of light-emitting devices arranged on the base substrate.

The plurality of light-emitting devices are located in the first display sub-area and the second display sub-area; the driving circuit layer includes a plurality of pixel driving circuits, a gate driving circuit, and a light emission control circuit; the plurality of pixel driving circuits are located in the first display sub-area and the peripheral area; the gate driving circuit and the light emission control circuit are located in the peripheral area.

A first electrode of each light-emitting device is electrically coupled to one pixel driving circuit; the gate driving circuit is configured to provide a scan signal to each of the plurality of pixel driving circuits; the light emission control circuit is configured to provide a light emission control signal to each of the plurality of pixel driving circuits.

The plurality of pixel driving circuits include first pixel driving circuits configured to provide driving signals for light-emitting devices in the first display sub-area, and second pixel driving circuits configured to provide driving signals for light-emitting devices in the second display sub-area.

The light emission control circuit includes a first light emission control sub-circuit and a second light emission control sub-circuit that are spaced apart and disconnected from each other; the first light emission control sub-circuit is configured to provide a light emission control signal to each of the first pixel driving circuits; the second light emission control sub-circuit is configured to provide a light emission control signal to each of the second pixel driving circuits.

In some embodiments, the plurality of pixel driving circuits include redundant pixel driving circuits located in the peripheral area; the light emission control circuit includes a redundant light emission control circuit; the redundant pixel driving circuits are used as the second pixel driving circuits; the redundant light emission control circuit is used as the second light emission control sub-circuit.

In some embodiments, the display area has a first side and a second side opposite to each other along a first direction, and a third side and a fourth side opposite to each other along a second direction; the second display sub-area is located on the third side in the display area; the second pixel driving circuits are located in the peripheral area and close to the third side of the display area.

In some embodiments, the second pixel driving circuits form a plurality of second pixel driving circuit groups arranged side by side along the second direction; second pixel driving circuits in each second pixel driving circuit group are arranged side by side along the first direction; all of the second pixel driving circuits in a same second pixel driving circuit group are coupled to a same redundant scan line and a same redundant light emission control line.

Any one of redundant scan lines and redundant light emission control lines includes a first end and a second end opposite to each other; each of the first end and the second end of each redundant scan line is coupled to a gate driving circuit; each of the first end and the second end of each redundant light emission control line is coupled to a second light emission control sub-circuit.

In some embodiments, the second light emission control sub-circuit coupled to the first end of the redundant light emission control line is located at a corner of the peripheral area close to the first side and the third side of the display area; and the second light emission control sub-circuit coupled to the second end of the redundant light emission control line is located at a corner of the peripheral area close to the second side and the fourth side of the display area.

In some embodiments, the gate driving circuit includes a first gate driving sub-circuit and a second gate driving sub-circuit that are spaced apart and disconnected from each other; the first gate driving sub-circuit is configured to provide a scan signal to each of the first pixel driving circuits; the second gate driving sub-circuit is configured to provide a scan signal to each of the second pixel driving circuits.

In some embodiments, the gate driving circuit includes a redundant gate driving circuit, and the redundant gate driving circuit is used as the second gate driving sub-circuit.

In some embodiments, the plurality of pixel driving circuits are arranged side by side along the second direction to form a plurality of pixel driving circuit groups; pixel driving circuits in each pixel driving circuit group are arranged side by side along the first direction.

All pixel driving circuits in a same pixel driving circuit group are coupled to a same scan line and a same light emission control line; any one of scan lines and light emission control lines includes a first end and a second end opposite to each other; each of the first end and the second end of each scan line is coupled to a gate driving circuit; each of the first end and the second end of each light emission control line is coupled to a light emission control circuit.

In some embodiments, the display area further includes a third display sub-area located between the first display sub-area and the second display sub-area.

The second pixel driving circuits are located in the third display sub-area.

In some embodiments, the second light emission control sub-circuit is coupled to first electrodes of the light-emitting devices through signal connection lines; the signal connection lines are transparent wires.

In a second aspect, embodiments of the present disclosure provide a display panel including the above-mentioned display substrate.

In some embodiments, the display panel further includes an external control circuit bonded to the display substrate and configured to separately control the first light emission control sub-circuit and the second light emission control sub-circuit.

### BRIEF DESCRIPTION OF DRAWINGS

FIG. 1 is a schematic diagram of an exemplary display substrate.

FIG. 2 is a schematic diagram of an exemplary pixel driving circuit.

FIG. 3 is a schematic diagram of an exemplary light emission control circuit.

FIG. 4 is a schematic circuit diagram of an exemplary first shift register.

FIG. 5 is a schematic diagram of an exemplary gate driving circuit.

FIG. 6 is a schematic circuit diagram of an exemplary second shift register.

FIG. 7 is a schematic diagram of a display substrate according to an embodiment of the present disclosure.

FIG. 8 is a schematic diagram of another display substrate according to an embodiment of the present disclosure.

FIG. 9 is a schematic diagram of still another display substrate according to an embodiment of the present disclosure.

FIG. 10 is a schematic diagram of a display device according to an embodiment of the present disclosure.

### DETAIL DESCRIPTION OF EMBODIMENTS

In order to enable those skilled in the art to better understand the technical solutions of the present disclosure, the present disclosure will be further described in detail below in conjunction with the accompanying drawings and specific embodiments.

Unless otherwise defined, the technical terms or scientific terms used in the present disclosure shall have the usual meanings understood by those with ordinary skills in the field to which this disclosure belongs. The words such as “first”, “second” and the like used in the present disclosure do not indicate any order, quantity or importance, but are only used to distinguish different components. Similarly, words such as “a”, “one”, “the” and the like do not mean a quantity limit, but rather mean that there is at least one. Words such as “include”, “comprise”, and the like mean that the element or item appearing before the word covers the element or item listed after the word and their equivalents, but do not exclude other elements or items. Words such as “connect”, “couple” and the like are not limited to physical or mechanical connections, but may include electrical connections, whether direct or indirect. Words such as “up”, “down”, “left”, “right”, and the like are only used to indicate the relative position relationship, and the relative position relationship may change accordingly when the absolute position of the described object changes.

With the development of display technology, the existing designs of notched screens or waterdrop screens are gradually unable to meet the user's demand for high screen-to-body ratio of display panels, and a series of display panels that can achieve display in an installation area have emerged as the times require. In this type of display panels, hardware such as a light-sensitive sensor (e.g., a camera) can be disposed in a display area. Because there is no need to form a hole, a true full screen is possible under the premise of ensuring the practicability of the display panel.

Before the following description, a first direction and a second direction mentioned in the present disclosure will be described. The first direction and the second direction indicate two different directions. For example: the first direction is a row direction, and the second direction is a column direction. For ease of understanding, in the following description, description is given by taking a case where the first direction is the row direction, and the second direction is the column direction as an example. Of course, it should be understood that cases in which the first direction and the second direction are two different directions are all within the protection scope of the present disclosure.

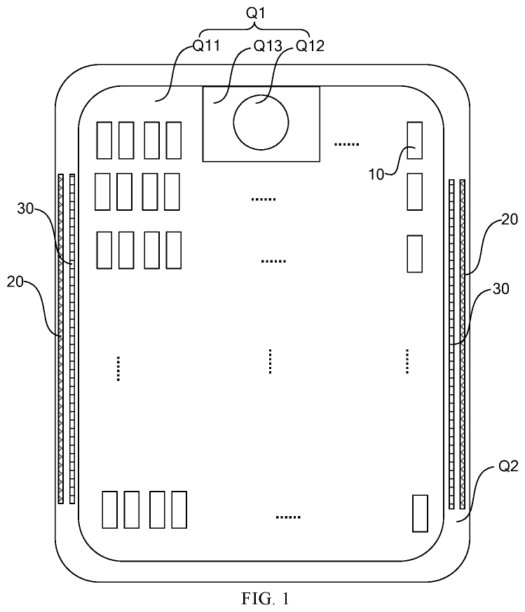

FIG. 1 is a schematic diagram of an exemplary display substrate; as shown in FIG. 1, the display substrate has a display area Q1 and a peripheral area Q2 surrounding the display area Q1. The display area Q1 is divided into a first display sub-area Q11, a second display sub-area Q12, and a third display sub-area Q13. The display substrate includes a base substrate, and a plurality of pixel units, a gate driving circuit 30 and a light emission control circuit 20 that are arranged on the base substrate.

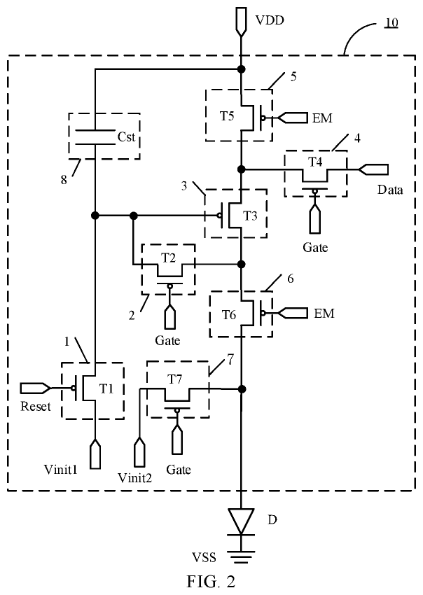

The plurality of pixel units are disposed in the display area Q1 of the display substrate and arranged in an array. Each pixel unit located in the first display sub-area Q11 includes a pixel driving circuit 10 and a light-emitting device electrically coupled to the pixel driving circuit 10. The second display sub-area Q12 is configured to accommodate hardware such as a light-sensitive sensor (e.g., a camera) therein. Each pixel unit in the second display sub-area Q12 is only provided with a light-emitting device, and the light-emitting device is a transparent light-emitting device to avoid affecting operation of the light-sensitive sensor. One part of the pixel units in the third display sub-area Q13 each include a pixel driving circuit 10 and a light-emitting device electrically coupled to the pixel driving circuit 10, the other part of the pixel units in the third display sub-area Q13 are each only provided with a pixel driving circuit 10, and the pixel driving circuits 10 of the other part of the pixel units in the third display sub-area Q13 are coupled to the light-emitting devices in the second display sub-areas Q12 in one-to-one correspondence to provide driving signals to the light-emitting devices in the second display sub-area Q12. It should be noted that signal connection lines that electrically couple the light-emitting devices in the second display sub-area Q12 to the pixel driving circuits 10 in the third display sub-area Q13 should be transparent wires (e.g., made of indium tin oxide (ITO)), so as to prevent the signal connection lines from affecting the operation of the light-sensitive sensor. FIG. 2 is a schematic diagram of an exemplary pixel driving circuit; as shown in FIG. 2, the pixel driving circuit 10 may include: a first reset sub-circuit 1, a threshold compensation sub-circuit 2, a data writing sub-circuit 4, a driving sub-circuit 3, a first light emission control sub-circuit 5, a second light emission control sub-circuit 6, a second reset sub-circuit 7, and a storage sub-circuit 8. Referring to FIG. 2, the first light emission control sub-circuit 5 is respectively coupled to a first voltage terminal VDD and a first terminal of the driving sub-circuit 3, and is configured to realize connection and disconnection between the driving sub-circuit 3 and the first voltage terminal VDD. The second light emission control sub-circuit 6 is electrically coupled to a second terminal of the driving sub-circuit and a first electrode of the light-emitting device D, and is configured to realize connection and disconnection between the driving sub-circuit 3 and the light-emitting device D. The data writing sub-circuit 4 is electrically coupled to the first terminal of the driving sub-circuit 3, and is configured to write a data signal into the storage sub-circuit 8 under the control of a scan signal. The storage sub-circuit 8 is electrically coupled to a control terminal of the driving sub-circuit 3 and the first voltage terminal VDD, and is configured to store the data signal. The threshold compensation sub-circuit 2 is electrically coupled to the control terminal and the second terminal of the driving sub-circuit 3, respectively, and is configured to perform threshold compensation on the driving sub-circuit 3. The first reset sub-circuit 1 is electrically coupled to the control terminal of the driving sub-circuit 3, and is configured to reset the control terminal of the driving sub-circuit 3 under the control of a reset control signal. The second reset sub-circuit 7 is electrically coupled to the first electrode of the light-emitting device D, and is configured to reset the first electrode of the light-emitting device D under the control of the scan signal.

Continuing to refer to FIG. 2, in the pixel driving circuit 10, the driving sub-circuit 3 includes a driving transistor T3, the data writing sub-circuit 4 includes a data writing transistor T4, the threshold compensation sub-circuit 2 includes a threshold compensation transistor T2, the first light emission control sub-circuit 5 includes a first light emission control transistor T5, the second light emission control sub-circuit 6 includes a second light emission control transistor T6, the first reset sub-circuit 1 includes a first reset transistor T1, and the second reset sub-circuit 7 includes a second reset transistor T7.

For the pixel driving circuit 10, it should be noted that transistors can be divided into N-type transistors and P-type transistors according to the characteristics thereof. For the sake of clarity, in the embodiments of the present disclosure, technical solutions of the present disclosure are described in detail by taking a case where the transistors are P-type transistors (e.g., P-type MOS transistors) as an example, that is, in the description of the present disclosure, the driving transistor T3, the data writing transistor T4, the threshold compensation transistor T2, the first light emission control transistor T5, the second light emission control transistor T6, the first reset transistor T1, and the second reset transistor T7 may all be P-type transistors. However, the transistors in the embodiments of the present disclosure are not limited to P-type transistors, and those skilled in the art can also use an N-type transistor (e.g., an N-type MOS transistor) or a combination of a P-type transistor and a N-type transistor to implement the function of one or more transistors in the embodiments of the present disclosure as practically required.

In addition, the transistors used in the embodiments of the present disclosure may be thin film transistors or field effect transistors or other switching devices with the same characteristics. The thin film transistors may include oxide semiconductor thin film transistors, amorphous silicon thin film transistors, or polysilicon thin film transistors. Each transistor includes a first electrode, a second electrode, and a control electrode; the control electrode refers to a gate of the transistor, one of the first electrode and the second electrode refers to a source of the transistor, and the other refers to a drain of the transistor. The source and the drain of the transistor may be symmetrical in structure, and therefore the source and the drain may be indistinguishable in physical structure. In the embodiments of the present disclosure, in order to distinguish the electrodes of the transistors, in addition to the gate serving as the control electrode, the first electrode is directly described as the source and the second electrode is the drain. Therefore, the source and the drain of each of all or part of the transistors in the embodiments of the present disclosure are interchangeable as required.

Continuing to refer to FIG. 2, the drain of the data writing transistor T4 is electrically coupled to the source of the driving transistor T3, the source of the data writing transistor T4 is configured to be electrically coupled to a data line Data to receive a data signal, and the gate of the data writing transistor T4 is electrically coupled to a scan line Gate to receive a scan signal. A first electrode plate of the storage capacitor Cst is electrically coupled to a first power supply voltage terminal VDD, and a second electrode plate of the storage capacitor Cst is electrically coupled to the gate of the driving transistor T3. The source of the threshold compensation transistor T2 is electrically coupled to the drain of the driving transistor T3, the drain of the threshold compensation transistor T2 is electrically coupled to the gate of the driving transistor T3, and the gate of the threshold compensation transistor T2 is configured to be electrically coupled to the scan line Gate to receive a compensation control signal. The source of the first reset transistor T1 is configured to be electrically coupled to an initialization signal terminal Vinit to receive an initialization signal, the drain of the first reset transistor T1 is electrically coupled to the gate of the driving transistor T3, and the gate of the first reset transistor T1 is configured to be electrically coupled to a first reset control signal line Reset to receive a reset control signal. The source of the second reset transistor T7 is configured to be electrically coupled to the initialization signal terminal Vinit to receive the initialization signal, the drain of the second reset transistor T7 is electrically coupled to the first electrode of the light-emitting device D, and the gate of the second reset transistor T7 is configured to be electrically coupled to the scan line Gate to receive the scan signal. The source of the first light emission control transistor T5 is electrically coupled to the first power supply voltage terminal VDD, the drain of the first light emission control transistor T5 is electrically coupled to the source of the driving transistor T3, and the gate of the first light emission control transistor T5 is configured to be electrically coupled to a light emission control signal line EM to receive a light emission control signal. The source of the second light emission control transistor T6 is electrically coupled to the drain of the driving transistor T3, the drain of the second light emission control transistor T6 is electrically coupled to the first electrode of the light-emitting device D, and the gate of the second light emission control transistor T6 is configured to be electrically coupled to the light emission control signal line EM to receive the light emission control signal. The second electrode of the light-emitting device D is electrically coupled to a second power supply voltage terminal VSS.

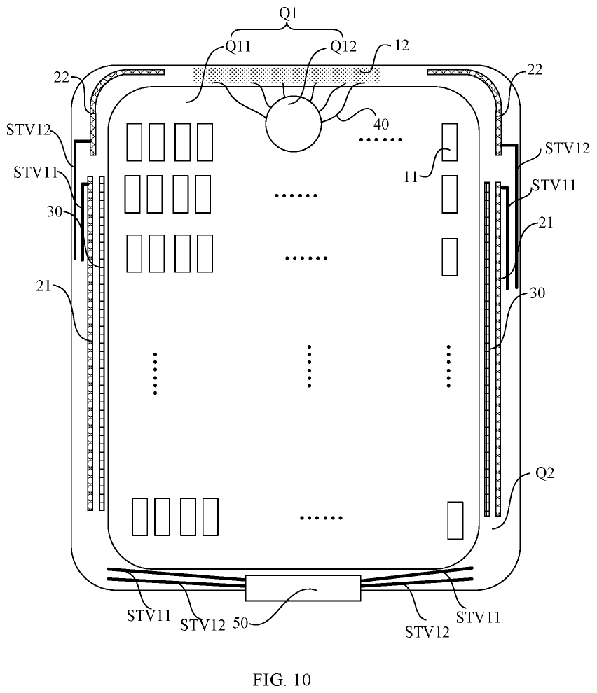

For example, one of the first power supply voltage terminal VDD and the second power supply voltage terminal VSS is a high-voltage terminal, and the other is a low-voltage terminal. For example, in the embodiment shown in FIG. 10, the first power supply voltage terminal VDD is a voltage source for outputting a constant first voltage, the first voltage being a positive voltage; and the second power supply voltage terminal VSS may be a voltage source for outputting a constant second voltage, the second voltage being a negative voltage. For example, in some examples, the second power supply voltage terminal VSS may be grounded.

It should be noted that the reset sub-circuit 1, the threshold compensation sub-circuit 2, the data writing sub-circuit 4, the driving sub-circuit 3, the first light emission control sub-circuit 5, the second light emission control sub-circuit 6, and the storage sub-circuit 7 in the pixel driving circuit 1010 shown in FIG. 2 are only illustrative, and the specific structures of the sub-circuits such as the reset sub-circuit 1, the threshold compensation sub-circuit 2, the data writing sub-circuit 4, the driving sub-circuit 3, the first light emission control sub-circuit 5, the second light emission control sub-circuit 6 and the storage sub-circuit 7 may be set according to actual application requirements, which are not specifically limited in the embodiments of the present disclosure.

The light-emitting device D may be a miniature inorganic light emitting diode, and further, may be a current-type light emitting diode, such as a micro light emitting diode (Micro LED) or a mini light emitting diode (Mini LED). Of course, the light-emitting device D in the embodiments of the present disclosure may also be an organic light emitting diode (OLED). One of the first electrode and the second electrode of the light-emitting device D is an anode, and the other is a cathode; in the embodiments of the present disclosure, description is given by taking a case where the first electrode of the light-emitting device D is the anode and the second electrode is the cathode as an example.

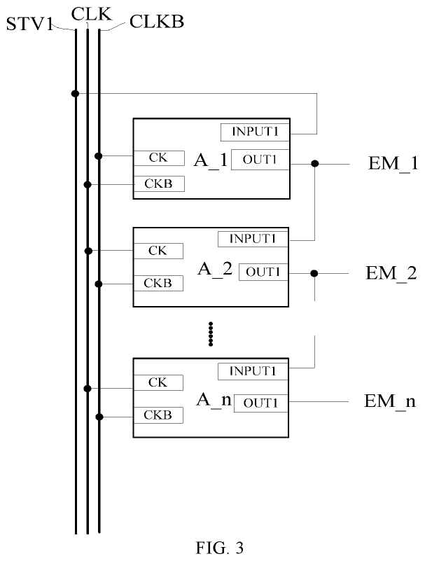

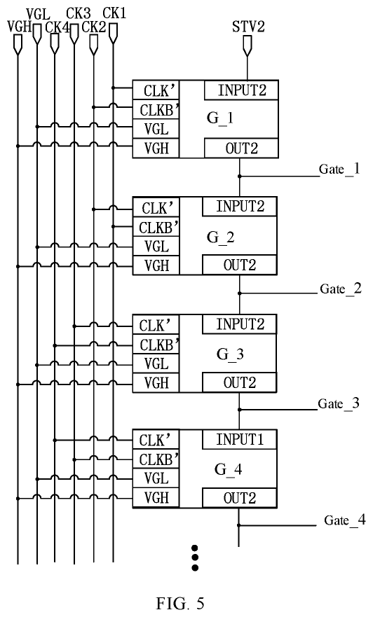

In some exemplary embodiments, the pixel driving circuits 10 in respective pixel units in the same row are provided with a scan signal from the same gate line, and provided with a light emission control signal from the same light emission control line. Any one of the gate lines and the light emission control lines includes a first end and a second end opposite to each other. The gate driving circuit 30 and the light emission control circuit 20 of the display substrate are located in the peripheral area Q2, both the first end and the second end of each gate line are coupled to the gate driving circuit 30, and both the first end and the second end of each light emission control line are coupled to the light emission control circuit 20. The gate driving circuit 30 and the light emission control circuit 20 are both located in the peripheral area Q2, and FIG. 3 is a schematic diagram of an exemplary light emission control circuit 20. As shown in FIG. 3, the light emission control circuit 20 includes a plurality of first shift registers A coupled in cascade, the plurality of first shift registers A in the light emission control circuit 20 are coupled to the light emission control lines in one-to-one correspondence and configured to provide light emission control signals, and a first signal output terminal of the first shift register A of the current stage is coupled to a first signal input terminal of the first shift register A of the next stage; in addition, the first signal input terminal INPUT1 of the first shift register A−1 of the first stage is coupled to a first frame starting signal STV1. FIG. 5 is a schematic diagram of an exemplary gate driving circuit 30. As shown in FIG. 5, the gate driving circuit 30 includes a plurality of second shift registers G coupled in cascade. The plurality of second shift registers G in the gate driving circuit 30 are coupled to the gate lines in one-to-one correspondence and configured to provide scan signals, and a second signal output terminal of the second shift register G of the current stage is coupled to a second signal input terminal of the second shift register G of the next stage; in addition, the second signal input terminal INPUT2 of the second shift register G−1 of the first stage is coupled to the second frame starting signal STV2.

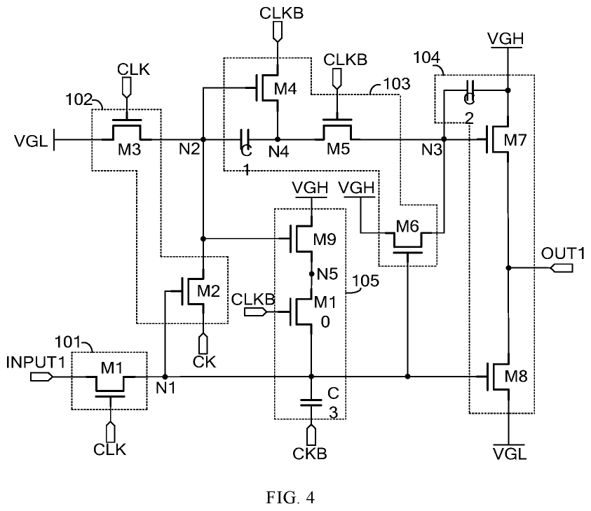

FIG. 4 is a schematic circuit diagram of an exemplary first shift register A; as shown in FIG. 4, the first shift register A includes: a signal writing circuit 101, a first control circuit 102, a second control circuit 103, and a signal output circuit 104. The signal writing circuit 101, the first control circuit 102, the second control circuit 103, and the signal output circuit 104 are coupled to a first node N1, both the first control circuit 102 and the second control circuit 103 are coupled to a second node N2, and both the second control circuit 103 and the signal output circuit 104 are coupled to a third node N3. The signal writing circuit 101 is coupled to the corresponding first signal input terminal INPUT and a first clock signal terminal CK, and is configured to write a signal provided by the corresponding first signal input terminal INPUT1 to the first node N1 in response to the control of a first clock signal provided by the first clock signal terminal CK. The first control circuit 102 is coupled to the first power supply terminal VGH and the first clock signal terminal CK, and is configured to write a first operating voltage provided by the first power supply terminal VGH to the second node N2 in response to the control of the first clock signal, and write the first clock signal to the second node N2 in response to the control of the voltage at the first node N. The second control circuit 103 is coupled to the second power supply terminal VGL and a second clock signal terminal CKB, and is configured to write, in response to the control of the voltage at the second node N2 and a second clock signal provided by the second clock signal terminal CKB, the second clock signal to the third node N3, and write a second operating voltage provided by the second power supply terminal VGL to the third node N3 in response to the control of the voltage at the first node N1. The signal output circuit 104 is coupled to the first power supply terminal VGH and the second power supply terminal VGL, and is configured to write the first operating voltage to the first signal output terminal OUT1 in response to the control of the voltage at the first node N1, and write the second operating voltage to the first signal output terminal OUT1 in response to the control of the voltage at the third node N3. A noise reduction circuit 105 is coupled to the first node N1, the second node N2, the second power supply terminal VGL, and the second clock signal terminal CKB, and is configured to denoise the voltage at the first node N1 in response to the control of the second clock signal and the voltage at the second node N2.

The signal writing circuit 101 includes a first transistor M1. The first control circuit 102 includes a second transistor M2 and a third transistor M3. The second control circuit 103 includes a fourth transistor M4, a fifth transistor M5, a sixth transistor M6, and a first capacitor C1. The signal output circuit 104 includes: a seventh transistor M7, an eighth transistor M8, and a second capacitor C2. The noise reduction circuit 105 includes: a ninth transistor M9, a tenth transistor M10, and a third capacitor C3. Description is given by taking a case where the first transistor M1, the second transistor M2, the third transistor M3, the fourth transistor M4, the fifth transistor M5, the sixth transistor M6, the seventh transistor M7, the eighth transistor M8, the ninth transistor M9 and the tenth transistor M10 are all N-type thin film transistors as an example.

The gate of the first transistor M1 is coupled to the first clock signal terminal CK, the source of the first transistor M1 is coupled to the first signal input terminal INPUT1, and the drain of the first transistor M1 is coupled to the first node N1. The gate of the second transistor M2 is coupled to the first node N1, the source of the second transistor M2 is coupled to the first clock signal terminal CK, and the drain of the second transistor M2 is coupled to the second node N2. The gate of the third transistor M3 is coupled to the first clock signal terminal CK, the source of the third transistor M3 is coupled to the first power supply terminal VGH, and the drain of the third transistor M3 is coupled to the second node N2. The gate of the fourth transistor M4 is coupled to the second node N2, the source of the fourth transistor M4 is coupled to the second clock signal terminal CKB, and the drain of the fourth transistor M4 is coupled to the source of the fifth transistor M5. The gate of the fifth transistor M5 is coupled to the second clock signal terminal CKB, and the drain of the fifth transistor M5 is coupled to the third node N3. The gate of the sixth transistor M6 is coupled to the first node N1, the source of the sixth transistor M6 is coupled to the second power supply terminal VGL, and the drain of the sixth transistor M6 is coupled to the third node N3. The first electrode plate of the first capacitor C1 is coupled to the second node N2, and the second electrode plate of the first capacitor C1 is coupled to the drain of the fourth transistor M4. The gate of the seventh transistor M7 is coupled to the third node N3, the source of the seventh transistor M7 is coupled to the second power supply terminal VGL, and the drain of the seventh transistor M7 is coupled to the first signal output terminal OUT1. The gate of the eighth transistor M8 is coupled to the first node N1, the source of the eighth transistor M8 is coupled to the first power supply terminal VGH, and the drain of the eighth transistor M8 is coupled to the first signal output terminal OUT1. The first electrode plate of the second capacitor C2 is coupled to the third node, and the second electrode plate of the second capacitor C2 is coupled to the first power supply terminal VGH.

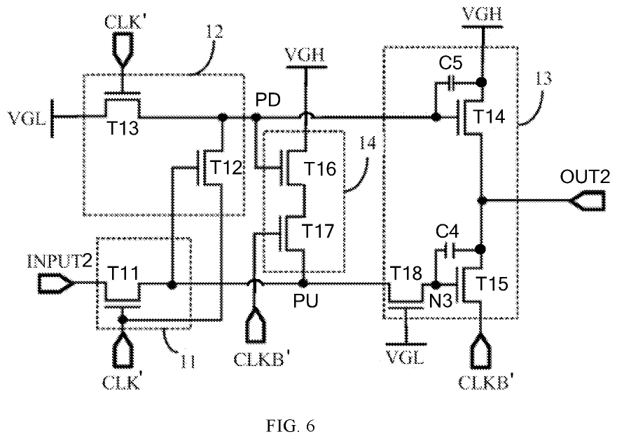

FIG. 6 is a schematic circuit diagram of an exemplary second shift register G; as shown in FIG. 6, the second shift register includes: a first input sub-circuit 11, a first pull-down control sub-circuit 12, a first output sub-circuit 13 and a first pull-down sub-circuit 14. The first input sub-circuit 11 is coupled to the second signal input terminal INPUT2, a pull-up node PU, and a third clock signal terminal CLK′, and is configured to write an input signal provided by the second signal input terminal INPUT2 to the pull-up node PU in response to the control of the third clock signal terminal CLK′. The first pull-down control sub-circuit 12 is coupled to the second power supply terminal VGL, the pull-up node PU, the pull-down node PD, and the third clock signal terminal CLK′, and is configured to write the first operating voltage provided by the second power supply terminal VGL to the pull-down node PD in response to the control of the third clock signal terminal CLK′, and write the first clock signal provided by the third clock signal terminal CLK′ to the pull-down node PD in response to the control of the voltage at the pull-up node PU. The first output sub-circuit 13 is coupled to the first power supply terminal VGH, the pull-up node PU, the pull-down node PD, the second signal output terminal OUT2, and a fourth clock signal terminal CLKB′, and is configured to write the second clock signal provided by the fourth clock signal terminal CLKB′ to the second signal output terminal OUT2 in response to the control of the voltage at the pull-up node PU, and write the second operating voltage provided by the first power supply terminal VGH to the second signal output terminal OUT2 in response to the control of the voltage at the pull-down node PD. The first pull-down sub-circuit 14 is coupled to the first power supply terminal VGH, the pull-up node PU, the pull-down node PD, and the fourth clock signal terminal CLKB′. The first pull-down sub-circuit 14 is configured to write the second operating voltage to the pull-up node PU in response to the control of the voltage at the pull-down node PD and the fourth clock signal terminal CLKB′.

The first input sub-circuit 11 includes an eleventh transistor T11. The first pull-down control sub-circuit 12 includes a twelfth transistor T12 and a thirteenth transistor T13. The first output sub-circuit 13 includes a fourteenth transistor T14, a fifteenth transistor T15, an eighteenth transistor T18, a fourth capacitor C4, and a fifth capacitor C5. The first pull-down sub-circuit 14 includes a sixteenth transistor T16 and a seventeenth transistor T17. A case where the eleventh transistor T11, the twelfth transistor T12, the thirteenth transistor T13, the fourteenth transistor T14, the fifteenth transistor T15, the sixteenth transistor T16, the seventeenth transistor T17 and the eighteenth transistor T18 are all P-type thin film transistors is taken as an example.

The gate of the eleventh transistor T11 is coupled to the third clock signal terminal CLK′, the source of the eleventh transistor T11 is coupled to the second signal input terminal INPUT2, and the drain of the eleventh transistor T11 is coupled to the pull-up node PU. The gate of the twelfth transistor T12 is coupled to the pull-up node PU, the source of the twelfth transistor T12 is coupled to the third clock signal terminal CLK′, and the drain of the twelfth transistor T12 is coupled to the pull-down node PD. The gate of the thirteenth transistor T13 is coupled to the third clock signal terminal CLK′, the source of the thirteenth transistor T13 is coupled to the second power supply terminal VGL, and the drain of the thirteenth transistor T13 is coupled to the pull-down node PD. The gate of the fourteenth transistor T14 is coupled to the pull-down node PD, the source of the fourteenth transistor T14 is coupled to the first power supply terminal VGH, and the drain of the fourteenth transistor T14 is coupled to the second signal output terminal OUT2. The gate of the fifteenth transistor T15 is coupled to the pull-up node PU, the source of the fifteenth transistor T15 is coupled to the fourth clock signal terminal CLKB′, and the drain of the fifteenth transistor T15 is coupled to the second signal output terminal OUT2. The gate of the sixteenth transistor T16 is coupled to the pull-down node PD, the source of the sixteenth transistor T16 is coupled to the first power supply terminal VGH, and the drain of the sixteenth transistor T16 is coupled to the source of the seventeenth transistor T17. The gate of the seventeenth transistor T17 is coupled to the fourth clock signal terminal CLKB′, and the drain of the seventeenth transistor T17 is coupled to the pull-up node PU. The gate of the eighteenth transistor T18 is coupled to the second power supply terminal VGL, the source of the eighteenth transistor T18 is coupled to the pull-up node PU, and the drain of the eighteenth transistor T18 is coupled to the gate of the fifteenth transistor T15. The first electrode plate of the fourth capacitor C4 is coupled to the gate of the fifteenth transistor T15, and the second electrode plate of the fourth capacitor C4 is coupled to the second signal output terminal OUT2. The first electrode plate of the fifth capacitor C5 is coupled to the pull-down node PD, and the second electrode plate of the fifth capacitor C5 is coupled to the source of the fourteenth transistor T14.

The inventor found that in the related art, the first shift register coupled to the pixel driving circuit for driving the light-emitting device in the second display sub-area and the first shift register coupled to the pixel driving circuit for driving the light-emitting device in the first display sub-area are coupled in cascade. In this way, even when the light-sensitive sensor in the second display sub-area needs to operate, the light-emitting device in the second display sub-area will be lit, which causes interference with the operation of the light-sensitive sensor. In view of this problem, the following technical solutions are provided in the embodiments of the present disclosure.

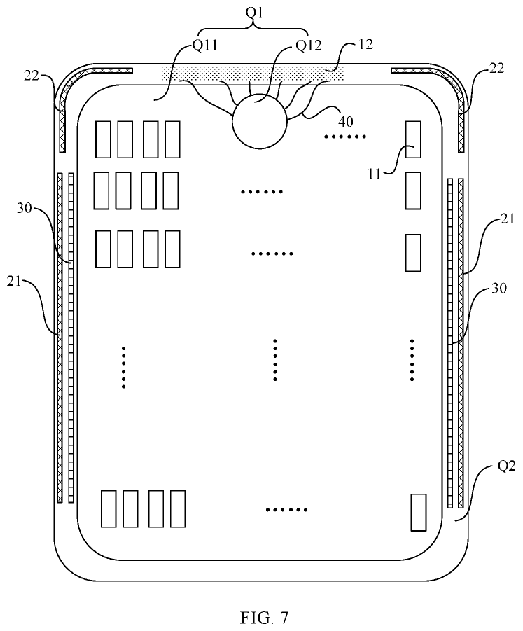

In a first aspect, FIG. 7 is a schematic diagram of a display substrate according to an embodiment of the present disclosure. As shown in FIG. 7, an embodiment of the present disclosure provides a display substrate having a display area Q1 and a peripheral area Q2 surrounding the display area Q1. The display area Q1 includes a first display sub-area Q11 and a second display sub-area Q12. The display substrate includes a driving circuit layer and a plurality of light-emitting devices. The driving circuit layer includes a plurality of pixel driving circuits, a gate driving circuit 30 and a light emission control circuit. Each pixel driving circuit is coupled to the first electrode of one light-emitting device to provide a driving current for the light-emitting device. The gate driving circuit 30 is configured to provide a scan signal for each pixel driving circuit, and the light emission control circuit is configured to provide a light emission control signal for each pixel driving circuit. The first display sub-area Q11 is not only provided with light-emitting devices, but also provided with pixel driving circuits for driving the light-emitting devices. The second display sub-area Q12 is configured to accommodate hardware such as a light-sensitive sensor (e.g., a camera) therein. Therefore, only light-emitting devices are provided in the second display sub-area Q12, and the light-emitting devices in this area are transparent light-emitting devices to avoid interference with the operation of the light-sensitive sensor. Pixel driving circuits for driving the light-emitting devices in the second display sub-area Q12 may be arranged in the first display sub-area Q11, or may be arranged in the peripheral area Q2. For the convenience of description, the pixel driving circuits for driving the light-emitting devices in the first display sub-area Q11 are referred to as first pixel driving circuits 11, and the pixel driving circuits for driving the light-emitting devices in the second display sub-area Q12 are referred to as second pixel driving circuits 12. In the embodiments of the present disclosure, the light emission control circuit includes a first light emission control sub-circuit 21 and a second light emission control sub-circuit 22 spaced apart and disconnected from each other. The first light emission control sub-circuit 21 is configured to provide an emission control signal to each first pixel driving circuit 11 and the second light emission control sub-circuit is configured to provide an emission control signal to each second pixel driving circuit.

It should be noted that both the first light emission control sub-circuit 21 and the second light emission control sub-circuit 22 may include a plurality of first shift registers that are cascaded, and the first shift register may have the circuit structure of the first shift register shown in FIG. 4. For example, one first shift register in the first light emission control sub-circuit 21 provides a light emission control signal for one row of first pixel driving circuits 11; one first shift register in the second light emission control sub-circuit 22 provides a light emission control signal for one row of second pixel driving circuits 12.

In the embodiments of the present disclosure, since the light emission control circuit includes the first light emission control sub-circuit 21 and the second light emission control sub-circuit 22 that are spaced apart and disconnected from each other, the first light emission control sub-circuit 21 provides light emission control signals to the first pixel driving circuits 11, and the second light emission control sub-circuit 22 provides light emission control signals to the second pixel driving circuits 12; that is, the first pixel driving circuits 11 are controlled by the first light emission control sub-circuit 21, and the second pixel driving circuits are controlled by the second light emission control sub-circuit. Therefore, when the light-sensitive sensor in the second display sub-area Q12 needs to operate, the second light emission control sub-circuit 22 can be controlled to output a non-operating level, so that the fifth transistors and the sixth transistors in the second pixel driving circuits 12 are turned off and the driving currents cannot be output to the light-emitting devices in the second display sub-area Q12. At this time, the light-emitting devices in the second display sub-area Q12 do not emit light, so no interference with the operation of the light-sensitive sensor is caused.

In some embodiments, the display substrate is not only provided with the pixel driving circuits in the display area Q1, but also the pixel driving circuits in the peripheral area Q2. In order to distinguish the pixel driving circuits in the display area Q1 from the pixel driving circuits in the peripheral area Q2, in the embodiments of the present disclosure, the pixel driving circuits in the peripheral area Q2 are referred to as redundant pixel driving circuits. It should be understood that the redundant pixel driving circuit may have the same structure as the pixel driving circuit in the display area Q1, and may use, for example, the 7T1C pixel driving circuit shown in FIG. 2. In the meanwhile, in the embodiments of the present disclosure, the light emission control circuit in the display substrate not only includes the first shift registers coupled in cascade, but also includes a plurality of redundant first shift registers having the same structure as the first shift register, and the plurality of redundant first shift registers are cascaded to form a redundant light emission control circuit. In the embodiments of the present disclosure, the redundant pixel driving circuit is used as the second pixel driving circuit 12 to provide driving currents for the light-emitting devices located in the second display sub-area Q12; at the same time, the redundant light emission control circuit may be used as the second light emission control sub-circuit 22 to provide light emission control signals for the redundant pixel driving circuits. In the embodiments of the present disclosure, the light-emitting devices located in the second display sub-area Q12 are driven by the redundant pixel driving circuit, in this way, the light-emitting devices in the display area Q1 may be uniformly arranged, and especially in the first display sub-area Q11, the pixel driving circuits may be coupled to the light-emitting devices in one-to-one correspondence, so that the display panel using the display substrate of the embodiments of the present disclosure can achieve more uniform display.

In an exemplary embodiment, continue to refer to FIG. 7 and a rectangular display substrate is taken as an example. The display area Q1 of the display substrate includes a first side (left side) and a second side (right side) opposite to each other in a row direction, and a third side (upper side) and a fourth side (lower side) opposite to each other in a column direction. The second display sub-area Q12 is located on the third side of the display area Q1, and the redundant pixel driving circuits located at a position of the peripheral area Q2 close to the third side of the display area Q1 are used as the second pixel driving circuits, which facilitates electrical connection between the second pixel driving circuits 12 and the light-emitting devices in the second display sub-area Q12. In some embodiments, the second pixel driving circuits 12 are electrically coupled to the light-emitting devices in the second display sub-area Q12 through signal connection lines 40, which may be transparent wires (e.g., wires made of indium tin oxide (ITO)).

For example, the second pixel driving circuits 12 form a plurality of second pixel driving circuit groups arranged side by side in the column direction, and second pixel driving circuits 12 in each second pixel driving circuit group are arranged side by side in the row direction. Since the redundant pixel driving circuits are used as the second pixel driving circuits 12, in this case, all the second pixel driving circuits 12 in the same second pixel driving circuit group are coupled to the same redundant scan line and the same redundant light emission control line. The redundant scan line and the redundant light emission control line each have a first end and a second end which are arranged oppositely, and the first end and the second end of the redundant scan line are each coupled to a gate driving circuit 30; the first end and the second end of the redundant light emission control line are each coupled to a second light emission control sub-circuit 22 (redundant light emission control circuit). It should be noted that each of the first end and the second end of one redundant light emission control line is coupled to one corresponding first shift register, and each of the first end and the second end of one redundant scan line is coupled to one corresponding second shifter register.

For example, continue to refer to FIG. 7, when the redundant light emission control circuit is used as the second light emission control sub-circuit 22, the redundant light emission control circuit (the second light emission control sub-circuit) coupled to the first end of the redundant light emission control line is located at a corner (upper left corner) of the peripheral area Q2 close to the first side and the third side of the display area Q1; the redundant light emission control circuit (second light emission control sub-circuit) coupled to the second end of the redundant light emission control line is located at a corner (upper right corner) of the peripheral area Q2 close to the second side and the fourth side of the display area Q1. The reason for this arrangement is to facilitate connection between the redundant light emission control circuit and the redundant pixel driving circuits.

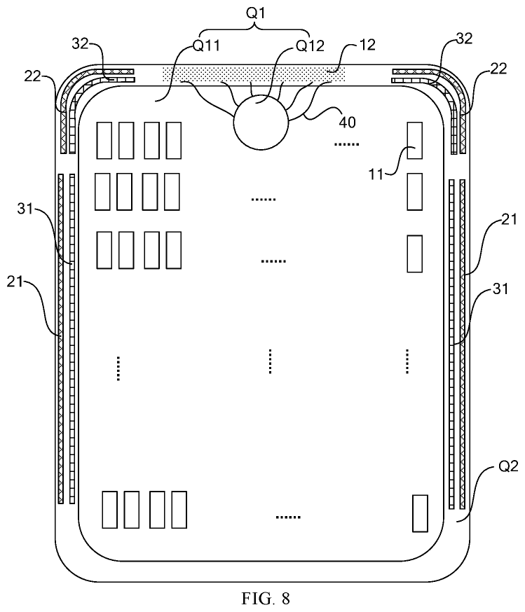

In some embodiments, FIG. 8 is a schematic diagram of another display substrate according to an embodiment of the present disclosure. As shown in FIG. 8, in the display substrate, not only the light emission control circuit includes the first and second light emission control sub-circuits 21 and 22 spaced apart and disconnected from each other, but also the gate driving circuit 30 includes a first gate driving sub-circuit 31 and a second gate driving sub-circuit 32 spaced apart and disconnected from each other. The first gate driving sub-circuit 31 is configured to provide a scan signal to each of the first pixel driving circuits 11; the second gate driving sub-circuit 32 is configured to provide a scan signal to each of the second pixel driving circuits 12. In the embodiments of the present disclosure, the first gate driving sub-circuit and the second gate driving sub-circuit 32 are respectively adopted to provide gate driving signals to the first pixel driving circuits and the second pixel driving circuits 12, and therefore, the second gate driving sub-circuit 32 may be controlled to stop operating when the light-sensitive sensor in the second display sub-area Q12 is operating, so as to reduce power consumption of the display substrate.

It should be noted that each of the first gate driving sub-circuit 31 and the second gate driving sub-circuit 32 includes second shift registers coupled in cascade. The second shift registers may all have the structure shown in FIG. 6. For example, one second shift register in the first gate driving sub-circuit 31 provides a scan signal to one row of first pixel driving circuits 11; one second shift register in the second gate driving sub-circuit 32 provides a scan signal to one row of second pixel driving circuits 12.

In some embodiments, the gate driving circuit 30 in the peripheral area Q2 not only includes second shift registers for providing scan signals to the pixel driving circuits in the display area Q1, but also includes redundant second shift registers having the same structure as the second shift register. The redundant second shift registers are cascaded to form a redundant gate driving circuit 30. In the embodiments of the present disclosure, the redundant gate driving circuit 30 may be used as the second gate driving sub-circuit 32.

For example, by taking the display substrate shown in FIG. 8 as an example, the redundant pixel driving circuits are used as the second pixel driving circuits 12, and the first end and the second end of each redundant scan line are each coupled to a redundant gate driving circuit 30 (second gate driving sub-circuit 32), the redundant gate driving circuit 30 coupled to the first end of the redundant scan line may be located at a position in the peripheral area Q2 near the upper left corner of the display area Q1, the redundant gate driving circuit 30 coupled to the second end of the redundant scan line may be located at a position in the peripheral area Q2 near the upper right corner of the display area Q1, so as to facilitate connection between the redundant gate driving circuits 30 and the redundant pixel driving circuits. It should be noted that each of the first end and the second end of each redundant scan line is coupled to one corresponding redundant shift register.

In some embodiments, the pixel driving circuits in the display substrate are arranged side by side along the column direction to form a plurality of pixel driving circuit groups; pixel driving circuits in each pixel driving circuit group are arranged side by side along the row direction. Pixel driving circuits located in the same row are coupled to the same scan line and the same light emission control line. Each of the scan lines and the light emission control lines includes a first end and a second end that are arranged oppositely, and each of the first end and the second end of each scan line is coupled to a gate driving circuit 30, and each of the first end and the second end of each light emission control line is coupled to a light emission control circuit. That is, the display substrate of the embodiment of the present disclosure adopts dual-sided driving. In this way, the charging time of the pixel driving circuit can be increased, and the refresh frequency can be increased.

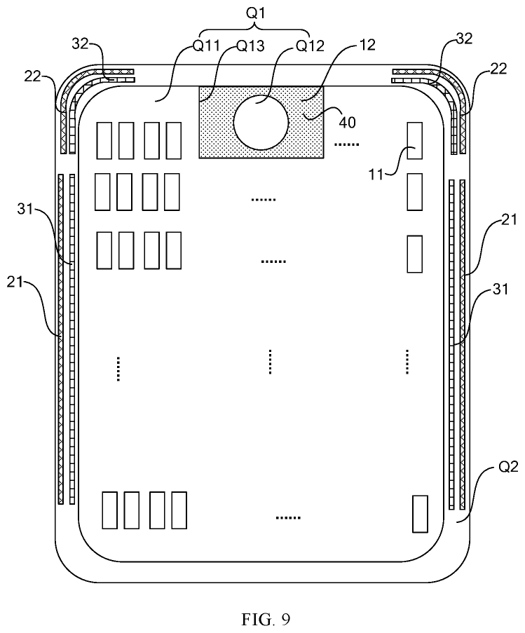

In some embodiments, FIG. 9 is a schematic diagram of another display substrate according to an embodiment of the present disclosure. As shown in FIG. 9, the display area Q1 not only includes the first display sub-area Q11 and the second display sub-area Q12, but also includes a third display sub-area Q13, and the third display sub-area Q13 may be arranged between the first display sub-area Q11 and the second display sub-area Q12. The arrangement density of light-emitting devices in the third display sub-area Q13 may be smaller than the arrangement density of the light-emitting devices in the first display sub-area Q11. In this case, the pixel driving circuits for driving the light-emitting devices in the second display sub-area Q12 are disposed in the third display sub-area Q13, that is, the second pixel driving circuits 12 are located in the third display sub-area Q13. The second pixel driving circuits 12 in the third display sub-area Q13 may be coupled to the first electrodes of the light-emitting devices in the second display sub-area Q12 through transparent wires.

It should be noted that the pixel driving circuits in the first display sub-area Q11 may be arranged in the same manner as the pixel driving circuits in the third display sub-area Q13. In this case, one part of the pixel driving circuits in the third display sub-area Q13 are electrically coupled to the first electrodes of the light-emitting devices in the third display sub-area Q13, and the other part of the pixel driving circuits in the third display sub-area Q13 are electrically coupled to the light-emitting devices in the second display sub-area Q12.

In a second aspect, FIG. 10 is a schematic diagram of a display device according to an embodiment of the present disclosure. As shown in FIG. 10, an embodiment of the present disclosure provides a display panel, which includes any of the above-mentioned display substrates. Of course, the display panel may also include an external control circuit 50 (e.g., timing controller/TCON) bonded to the display substrate and configured to provide control signals for the gate driving circuit 30 and the light emission control circuit. Because the light emission control circuit includes the first light emission control sub-circuit 21 and the second light emission control sub-circuit 22, which are spaced apart and disconnected from each other, the external control circuit 50 may be coupled to the first light emission control sub-circuit 21 and the second light emission control sub-circuit 22 through two separate frame starting signal lines STV11 and STV12, respectively, so as to achieve separate control of the first light emission control sub-circuit 21 and the second light emission control sub-circuit 22. It should be noted that STV11 is coupled to the first signal input terminal of the first register in the first light emission control sub-circuit 21 to control whether the first light emission control sub-circuit 21 operates, and STV12 is coupled to the first signal input terminal of the first register in the second light emission control sub-circuit 22 to control whether the second light emission control sub-circuit 22 operates. The display panel may be an electroluminescent display device, such as an OLED panel, a Micro LED panel, a Mini LED panel, a mobile phone, a tablet computer, a TV, a monitor, a notebook computer, a digital photo frame, a navigator or other product or component with display function. It could be understood that the above implementations are merely exemplary implementations used to illustrate the principle of the present disclosure, but the present disclosure is not limited thereto. For those of ordinary skill in the art, various modifications and improvements may be made without departing from the spirit and essence of the present disclosure, and these modifications and improvements are also deemed to be within the protection scope of the present disclosure.

1. A display substrate, having a display area and a peripheral area surrounding the display area; the display area comprising a first display sub-area and a second display sub-area; wherein the display substrate comprises a base substrate, and a driving circuit layer and a plurality of light-emitting devices on the base substrate;
the plurality of light-emitting devices are in the first display sub-area and the second display sub-area; the driving circuit layer comprises a plurality of pixel driving circuits, a gate driving circuit, and a light emission control circuit; the plurality of pixel driving circuits are in the first display sub-area and the peripheral area; the gate driving circuit and the light emission control circuit are in the peripheral area;
a first electrode of each light-emitting device is electrically coupled to one pixel driving circuit; the gate driving circuit is configured to provide a scan signal to each of the plurality of pixel driving circuits; the light emission control circuit is configured to provide a light emission control signal to each of the plurality of pixel driving circuits;
wherein the plurality of pixel driving circuits comprise first pixel driving circuits configured to provide driving signals to light-emitting devices in the first display sub-area, and second pixel driving circuits configured to provide driving signals to light-emitting devices in the second display sub-area; and
the light emission control circuit comprises a first light emission control sub-circuit and a second light emission control sub-circuit that are spaced apart and disconnected from each other; the first light emission control sub-circuit is configured to provide a light emission control signal to each of the first pixel driving circuits; the second light emission control sub-circuit is configured to provide a light emission control signal to each of the second pixel driving circuits.

2. The display substrate of claim 1, wherein the plurality of pixel driving circuits comprise redundant pixel driving circuits in the peripheral area; the light emission control circuit comprises a redundant light emission control circuit; the redundant pixel driving circuits are used as the second pixel driving circuits; the redundant light emission control circuit is used as the second light emission control sub-circuit.

3. The display substrate of claim 2, wherein the display area has a first side and a second side opposite to each other along a first direction, and a third side and a fourth side opposite to each other along a second direction; the second display sub-area is on the third side of the display area; the second pixel driving circuits are in the peripheral area and close to the third side of the display area.

4. The display substrate of claim 3, wherein the second pixel driving circuits form a plurality of second pixel driving circuit groups arranged side by side along the second direction; all second pixel driving circuits in each second pixel driving circuit group are arranged side by side along the first direction; all second pixel driving circuits in a same second pixel driving circuit group are coupled to a same redundant scan line and a same redundant light emission control line; and
any one of redundant scan lines and redundant light emission control lines comprises a first end and a second end opposite to each other; each of the first end and the second end of each redundant scan line is coupled to a gate driving circuit; each of the first end and the second end of each redundant light emission control line is coupled to a second light emission control sub-circuit.

5. The display substrate of claim 4, wherein the second light emission control sub-circuit coupled to the first end of the redundant light emission control line is at a corner of the peripheral area close to the first side and the third side of the display area; and the second light emission control sub-circuit coupled to the second end of the redundant light emission control line is at a corner of the peripheral area close to the second side and the fourth side of the display area.

6. The display substrate of claim 2, wherein the gate driving circuit comprises a first gate driving sub-circuit and a second gate driving sub-circuit that are spaced apart and disconnected from each other; the first gate driving sub-circuit is configured to provide a scan signal to each of the first pixel driving circuits; the second gate driving sub-circuit is configured to provide a scan signal to each of the second pixel driving circuits.

7. The display substrate of claim 6, wherein the gate driving circuit comprises a redundant gate driving circuit, and the redundant gate driving circuit is used as the second gate driving sub-circuit.

8. The display substrate of claim 1, wherein the plurality of pixel driving circuits are arranged side by side along a second direction to form a plurality of pixel driving circuit groups; pixel driving circuits in each pixel driving circuit group are arranged side by side along a first direction; and
all pixel driving circuits in a same pixel driving circuit group are coupled to a same scan line and a same light emission control line; any one of scan lines and light emission control lines comprises a first end and a second end opposite to each other; each of the first end and the second end of each scan line is coupled to a gate driving circuit; each of the first end and the second end of each light emission control line is coupled to a light emission control circuit.

9. The display substrate of claim 1, wherein the display area further comprises a third display sub-area between the first display sub-area and the second display sub-area; and
the second pixel driving circuits are in the third display sub-area.

10. The display substrate of claim 1, wherein the second light emission control sub-circuit is coupled to first electrodes of the light-emitting devices through signal connection lines; the signal connection lines are transparent wires.

11. A display panel, comprising the display substrate of claim 1.

12. The display panel of claim 11, further comprising an external control circuit bonded to the display substrate and configured to separately control the first light emission control sub-circuit and the second light emission control sub-circuit.

13. The display substrate of claim 3, wherein the gate driving circuit comprises a first gate driving sub-circuit and a second gate driving sub-circuit that are spaced apart and disconnected from each other; the first gate driving sub-circuit is configured to provide a scan signal to each of the first pixel driving circuits; the second gate driving sub-circuit is configured to provide a scan signal to each of the second pixel driving circuits.

14. The display substrate of claim 13, wherein the gate driving circuit comprises a redundant gate driving circuit, and the redundant gate driving circuit is used as the second gate driving sub-circuit.

15. The display substrate of claim 4, wherein the gate driving circuit comprises a first gate driving sub-circuit and a second gate driving sub-circuit that are spaced apart and disconnected from each other; the first gate driving sub-circuit is configured to provide a scan signal to each of the first pixel driving circuits; the second gate driving sub-circuit is configured to provide a scan signal to each of the second pixel driving circuits.

16. The display substrate of claim 15, wherein the gate driving circuit comprises a redundant gate driving circuit, and the redundant gate driving circuit is used as the second gate driving sub-circuit.

17. The display substrate of claim 5, wherein the gate driving circuit comprises a first gate driving sub-circuit and a second gate driving sub-circuit that are spaced apart and disconnected from each other; the first gate driving sub-circuit is configured to provide a scan signal to each of the first pixel driving circuits; the second gate driving sub-circuit is configured to provide a scan signal to each of the second pixel driving circuits.

18. The display substrate of claim 17, wherein the gate driving circuit comprises a redundant gate driving circuit, and the redundant gate driving circuit is used as the second gate driving sub-circuit.
